(19) United States
(12) Patent Application Publication
(10) Pub. No.: US 2026/0133478 A1
(43) Pub. Date: May 14, 2026

(54) EXTREME ULTRAVIOLET MASK

(71) Applicant: Samsung Electronics Co., Ltd., Suwon-si (KR)

(72) Inventors: Gilwoo Kong, Suwon-si (KR); Byeongwook Kim, Suwon-si (KR); Youngchang Seo, Suwon-si (KR); Heejung Oh, Suwon-si (KR)

(21) Appl. No.: 19/203,365

(22) Filed: May 9, 2025

(30) Foreign Application Priority Data
Nov. 13, 2024 (KR) 10-2024-0161334

(51) Int. Cl. G03F 1/24

(52) U.S. Cl. CPC G03F 1/24

(57) ABSTRACT

An extreme ultraviolet (EUV) mask configured to improve exposure characteristics and a patterning margin is provided. The EUV mask includes a substrate having a reflective mask thereon, a multi-reflective layer on a top surface of the substrate and including a plurality of layers comprising two kinds of material layers alternately stacked, and a phase-shift structure on the multi-reflective layer and including a transfer pattern and a non-transfer pattern, wherein the transfer pattern includes a first transfer pattern having a multi-layer structure, wherein the non-transfer pattern has a layered structure, and wherein an upper surface of the non-transfer pattern is closer to the substrate than an upper surface of the first transfer pattern.

### CROSS-REFERENCE TO RELATED APPLICATION

This application is based on and claims priority under 35 U.S.C. § 119 to Korean Patent Application No. 10-2024-0161334, filed on Nov. 13, 2024, in the Korean Intellectual Property Office, the disclosure of which is incorporated by reference herein in its entirety.

### BACKGROUND

The inventive concept relates to a mask, and more particularly, to an extreme ultraviolet (EUV) mask used in an EUV exposure process.

To meet the high performance and low prices demanded by consumers, the size of patterns formed on semiconductor substrates is getting smaller. To satisfy such technical demands, the wavelengths of light sources used in lithography are getting shorter. For example, lithography has used light of g-line (436 nm) and i-line (365 nm) in the past and currently uses light in a deep ultraviolet (DUV) band and light in an EUV band. Because light in the EUV band is mostly absorbed by refractive optical materials, EUV lithography may generally be carried out using reflective optical systems rather than refractive optical systems. In EUV lithography, a reflective mask may be used instead of a transmissive mask.

### SUMMARY

The inventive concept provides an extreme ultraviolet (EUV) configured to improve exposure characteristics and a patterning margin.

Also, the problems to be solved by embodiments of the present inventive concept are not limited to those mentioned above, and embodiments of the inventive concept can be clearly understood by those skilled in the art from the description below.

According to an aspect of the inventive concept, there is provided an EUV mask including a substrate having a reflective mask thereon, a multi-reflective layer on a top surface of the substrate and including a plurality of layers comprising two kinds of material layers alternately stacked, and a phase-shift structure on the multi-reflective layer and including a transfer pattern and a non-transfer pattern, wherein the transfer pattern includes a first transfer pattern having a multi-layer structure, wherein the non-transfer pattern has a layered structure, and wherein an upper surface of the non-transfer pattern is closer to the substrate than an upper surface of the first transfer pattern.

According to another aspect of the inventive concept, there is provided an EUV mask including a substrate having a reflective mask thereon, a backside conductive layer on a bottom surface of the substrate, a multi-reflective layer on a top surface of the substrate and including a plurality of layers comprising two kinds of material layers alternately stacked, a capping layer on the multi-reflective layer, and a phase-shift structure on the capping layer, wherein the phase-shift structure includes a first transfer pattern, a second transfer pattern, and a non-transfer pattern, the first transfer pattern having a multi-layer structure, and the second transfer pattern and the non-transfer pattern each having a layered structure, and wherein upper surfaces of the second transfer pattern and the non-transfer pattern, respectively, are closer to the substrate than an upper surface of the first transfer pattern.

According to a further aspect of the inventive concept, there is provided an EUV mask including a substrate having a reflective mask thereon, a multi-reflective layer on a top surface of the substrate and including a plurality of layers comprising two kinds of material layers alternately stacked, a capping layer on the multi-reflective layer, and a phase-shift structure on the multi-reflective layer and including a transfer pattern and a non-transfer pattern, wherein the transfer pattern includes a first transfer pattern having a multi-layer structure and a second transfer pattern having a layered structure, wherein an upper surface of the second transfer pattern is closer to the substrate than an upper surface of the first transfer pattern.

### BRIEF DESCRIPTION OF THE DRAWINGS

Embodiments will be more clearly understood from the following detailed description taken in conjunction with the accompanying drawings in which:

FIGS. 1A and 1B are respectively a cross-sectional view and a plan view of an extreme ultraviolet (EUV) mask according to an embodiment;

FIGS. 2A and 2B are respectively a cross-sectional view and a plan view of an EUV mask according to an embodiment;

FIGS. 3A and 3B are respectively a cross-sectional view and a plan view of an EUV mask according to an embodiment;

FIGS. 4A to 4C are cross-sectional views of an EUV mask according to an embodiment;

FIGS. 5A to 5C are simulation graphs illustrating exposure characteristics in three different EUV mask structures;

FIGS. 6A to 6C are simulation graphs illustrating exposure characteristics in three different EUV mask structures; and

FIGS. 7A to 7J are cross-sectional views schematically illustrating a method of manufacturing an EUV mask, according to an embodiment.

### DETAILED DESCRIPTION OF THE EMBODIMENTS

Hereinafter, embodiments are described in detail with reference to the accompanying drawings. In the drawing, like reference characters denote like elements, and redundant descriptions thereof will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

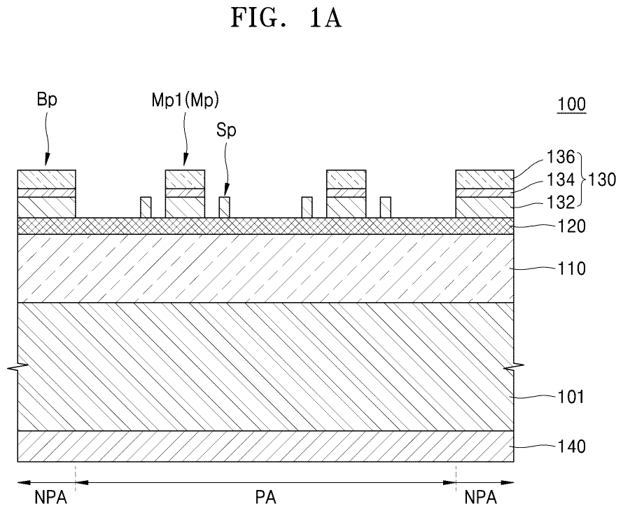

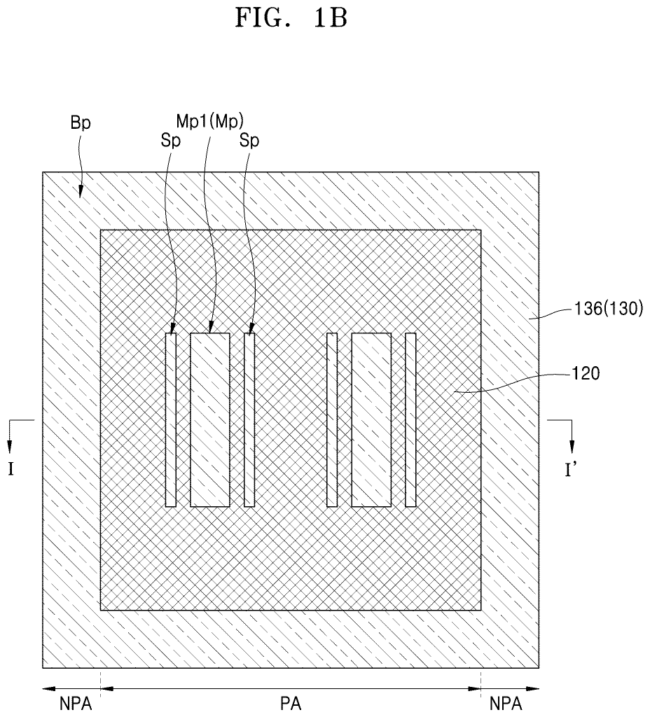

FIGS. 1A and 1B are respectively a cross-sectional view and a plan view of an extreme ultraviolet (EUV) mask according to an embodiment. FIG. 1A is a cross-sectional view taken along line I-I′ in FIG. 1B.

Referring to FIGS. 1A and 1B, an EUV mask 100 may include a substrate 101, a multi-reflective layer 110, a capping layer 120, a phase-shift structure 130, and a backside conductive layer 140. The substrate 101, the multi-reflective layer 110, the capping layer 120, and the backside conductive layer 140 may have a quadrangular shape in a plan view, as may be seen from FIG. 1B.

The substrate 101 may include a low thermal expansion material (LTEM). In other words, the substrate 101 may include a material having a low coefficient of thermal expansion (CTE). For example, the substrate 101 may include glass, silicon (Si), or quartz. However, the material of the substrate 101 is not limited to those mentioned above in accordance with different embodiments. The substrate 101 may have a thickness of about 6 mm. However, the thickness of the substrate 101 is not limited to the numerical range described above in accordance with different embodiments.

A transfer region PA and a non-transfer region NPA may be defined in the substrate 101. The transfer region PA may be arranged in the central region of the substrate 101, and the non-transfer region NPA may be arranged in an outer portion surrounding the transfer region PA as shown in FIG. 1B. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The transfer region PA may refer to a region in which patterns to be transferred to a wafer through an EUV exposure process are arranged. The patterns to be transferred to a wafer may be included in the phase-shift structure 130. In correspondence to the transfer region PA and the non-transfer region NPA defined in the substrate 101, the phase-shift structure 130 may also be divided into the transfer region PA and the non-transfer region NPA. Accordingly, the patterns to be transferred to a wafer may be arranged in the transfer region PA of the phase-shift structure 130.

The multi-reflective layer 110 may be disposed on the substrate 101. The multi-reflective layer 110 may reflect light, e.g., EUV rays, incident thereto. The multi-reflective layer 110 may include a Bragg reflector. In the EUV mask 100 of the present embodiment, the multi-reflective layer 110 may have a multi-layer structure in which two different kinds of material layers are alternately stacked. In some embodiments, the multi-layer structure may include several tens of layers. For example, the multi-reflective layer 110 may include first material layers and second material layers, which are alternately stacked. In the EUV mask 100 of the present embodiment, the first material layers and the second material layers may be alternately stacked and may include about 40 layers to about 60 layers. In other words, when a first material layer and a second material layer are considered as one pair, about 40 pairs to about 60 pairs of first and second material layers may be stacked on the substrate 101. The multi-reflective layer 110 may have a thickness of about 280 nm. However, the number of pairs of a first material layer and a second material layer and the thickness of the multi-reflective layer 110 are not limited to the numerical ranges described above in accordance with different embodiments.

The first material layer may correspond to a low-refractive index layer, and the second material layer may correspond to a high-refractive index layer. Accordingly, the second material layer may have a higher refractive index than the first material layer. For example, the first material layer may include molybdenum (Mo), and the second material layer may include Si. However, the materials of the first material layer and the second material layer are not limited to those described above in accordance with different embodiments. In the EUV mask 100 of the present embodiment, a first material layer corresponding to a low-refractive index layer may be arranged at the bottom of the multi-reflective layer 110, and a second material layer corresponding to a high-refractive index layer may be arranged at the top of the multi-reflective layer 110.

In some embodiments, the planar area of the multi-reflective layer 110 may be less than the planar area of the substrate 101. In this case, the multi-reflective layer 110 may not be arranged in an outer portion of the top surface of the substrate 101. For example, there may be an edge region having a quadrangular ring shape in the top surface of the substrate 101, and the multi-reflective layer 110 may not be arranged in the edge region.

The capping layer 120 may be disposed on the multi-reflective layer 110. For example, the capping layer 120 may cover the top surface of the multi-reflective layer 110. The term “covers” (or “covering,” or like terms), as may be used herein, is intended to broadly refer to an element, structure or layer that is on or over another element, structure or layer, either directly or with one or more other intervening elements, structures or layers therebetween. In some embodiments, when the substrate 101 includes the edge region, the capping layer 120 may extend from the top surface of the multi-reflective layer 110 and cover the side surface of the multi-reflective layer 110 and the edge region of the substrate 101.

The capping layer 120 may prevent or reduce damage to the multi-reflective layer 110 and surface oxidation of the multi-reflective layer 110. In the EUV mask 100 of the present embodiment, the capping layer 120 may cover the top surface of, for example, a second material layer, and prevent or reduce the second material layer from being oxidized. For example, the capping layer 120 may have a thickness of about 1 nm to about 5 nm. For example, the capping layer 120 may include a ruthenium (Ru)-group material. However, the thickness and material of the capping layer 120 are not limited to the numerical range and the Ru-group material described above in accordance with different embodiments. In some embodiments, the capping layer 120 may be omitted.

The phase-shift structure 130 may be disposed on the capping layer 120. In some embodiments, the capping layer 120 may be omitted. In this case, the phase-shift structure 130 may be disposed on the multi-reflective layer 110. When the EUV mask 100 of the present embodiment includes the phase-shift structure 130, the EUV mask 100 may be referred to as a phase-shift mask (PSM). In general, the phase-shift structure 130 may generate a phase difference in light reflected from the EUV mask 100 to ensure a clear contrast ratio even for micropatterns, thereby allowing the micropatterns to be clearly transferred to a wafer. General EUV masks are used to form micropatterns having a small line width. When the line width becomes very small below a few nm, light interference may significantly increases, and it may be difficult to clearly transfer the micropatterns. To solve this problem, a PSM may be applied to an EUV mask.

In the EUV mask 100 of the present embodiment, the phase-shift structure 130 may include a transfer pattern M p, a non-transfer pattern Sp, and a peripheral pattern Bp and may have different layered structures according to the type of patterns. The transfer pattern Mp and the non-transfer pattern Sp may be arranged in the transfer region PA, and the peripheral pattern Bp may be arranged in the non-transfer region NPA.

The transfer pattern M p may be transferred to a wafer and may correspond to a main feature. In the EUV mask 100 of the present embodiment, the transfer pattern Mp may include a first transfer pattern M p1 having a multi-layer structure. For example, the first transfer pattern M p1 may have a triple-layer structure including a first phase-shift layer 132, a buffer layer 134, and a second phase-shift layer 136. As may be seen from FIG. 1B, the first transfer pattern M p1 may have an isolated line shape. Here, “being isolated” may mean not being influenced by surrounding patterns. However, the shape of the first transfer pattern M p1 is not limited to the isolated line shape in accordance with different embodiments.

The first phase-shift layer 132 may have a reflectance of at least 6% and a phase shift of about 120° to about 200° with respect to EUV light. To realize the reflectance and the phase shift described above, the first phase-shift layer 132 may include a material having a low refractive index and low extinction coefficient with respect to EUV light. For example, the first phase-shift layer 132 may include a first material having a low refractive index and a low extinction coefficient and a second material for improving process characteristics, such as an etch rate and chemical resistance. The first phase-shift layer 132 may additionally include a third material of a light element. In detail, the first material may include at least one element selected from the group consisting of Pd, Rh, Ru, Tc, Mo, Nb, Zr, and Y. The second material may include at least one metal. The third material may include at least one element selected from the group consisting of H, He, B, C, O, and N.

For example, the first phase-shift layer 132 may have a thickness of about 1 nm to about 58 nm. However, the thickness of the first phase-shift layer 132 is not limited to the numerical range described above in accordance with different embodiments. For example, the total thickness of the phase-shift structure 130 may be 60 nm or less. In the EUV mask 100 of the present embodiment, the total thickness of the phase-shift structure 130 may be 50 nm or less. However, the total thickness of the phase-shift structure 130 is not limited to the numerical ranges described above in accordance with different embodiments. Accordingly, the thickness of the first phase-shift layer 132 may be appropriately adjusted considering the total thickness of the phase-shift structure 130.

The buffer layer 134 may be disposed on the first phase-shift layer 132. For example, the buffer layer 134 may be between the first phase-shift layer 132 and the second phase-shift layer 136. The buffer layer 134 may be provided to separate the first phase-shift layer 132 from the second phase-shift layer 136. The buffer layer 134 may also be used as an etch stop layer when the second phase-shift layer 136 is etched. Accordingly, the buffer layer 134 may have a high etch selectivity with respect to the second phase-shift layer 136. For example, the buffer layer 134 may have an etch selectivity of at least 1:5 with respect to the second phase-shift layer 136. In the EUV mask 100 of the present embodiment, the buffer layer 134 may have an etch selectivity of at least 1:10 with respect to the second phase-shift layer 136. However, the etch selectivity of the buffer layer 134 with respect to the second phase-shift layer 136 is not limited to those numerical ranges described above in accordance with different embodiments. When the buffer layer 134 has an etch selectivity of 1:5 with respect to the second phase-shift layer 136, that is, when a ratio of the etch rate of the buffer layer 134 to the etch rate of the second phase-shift layer 136 is 1:5, the buffer layer 134 may be etched by 1 measurement unit while the second phase-shift layer 136 is etched by 5 measurement units.

The buffer layer 134 may have a thickness that reduces or minimizes the influence on the optical characteristics of the phase-shift structure 130. For example, the buffer layer 134 may have a thickness of 10 nm or less. In the EUV mask 100 of the present embodiment, the buffer layer 134 may have a thickness of 5 nm or less. However, the thickness of the buffer layer 134 is not limited to the numerical ranges described above in accordance with different embodiments.

The second phase-shift layer 136 may be disposed on the buffer layer 134. The second phase-shift layer 136 may include substantially the same material as the first phase-shift layer 132. For example, the second phase-shift layer 136 may have a thickness of about 1 nm to about 58 nm. As described above, the total thickness of the phase-shift structure 130 may be 60 nm or less or 50 nm or less. Accordingly, the thickness of the second phase-shift layer 136 may be appropriately adjusted considering the total thickness of the phase-shift structure 130. The phase-shift structure 130 having a triple-layer structure including the first phase-shift layer 132, the buffer layer 134, and the second phase-shift layer 136 may have, for example, a reflectance of at least 4% and a phase shift of about 140° to about 240°. However, the reflectance and phase shift of the phase-shift structure 130 having a triple-layer structure are not limited to the numerical ranges described above in accordance with different embodiments.

The non-transfer pattern Sp may not be transferred to a wafer and may correspond to an assist feature for the main feature corresponding to the transfer pattern M p. For example, the non-transfer pattern Sp may include a sub-resolution assist feature (SRA F) such as a scattering bar. In general, SRAF may be an assist feature introduced to solve a deviation problem caused by optical proximity correction (OPC) and secure a depth of focus (DoF) when there is a density difference between patterns of a chip.

SRAF may not be a pattern that is actually supposed to be formed in a wafer. SRAF should not be transferred to a wafer. Accordingly, the non-transfer pattern Sp may have a size that is less than or equal to resolution. For example, the non-transfer pattern Sp may have a line width of 10 nm or less. In the EUV mask 100 of the present embodiment, the non-transfer pattern Sp may have a line width of 6 nm or less. However, the line width of the non-transfer pattern Sp is not limited to the numerical ranges described above in accordance with different embodiments.

The non-transfer pattern Sp may have a single-layer structure. For example, the non-transfer pattern Sp may include only the first phase-shift layer 132. The material and thickness of the first phase-shift layer 132 have been described above in the description of the first phase-shift layer 132 of the first transfer pattern M p1. The non-transfer pattern Sp may be adjacent to the first transfer pattern M p1 and may have a line shape. However, the shape of the non-transfer pattern Sp is not limited to the line shape in accordance with different embodiments.

In the EUV mask 100 of the present embodiment, because the non-transfer pattern Sp has a single-layer structure unlike the first transfer pattern M p1, the non-transfer pattern Sp may not be transferred to a wafer even when the non-transfer pattern Sp has a relatively large line width. To secure the resolution of patterns on a multi-layer reflective layer, an EUV PSM having a high normalized image log scale (NILS) characteristic may be used. With respect to an exposure process margin, an SRAF may be additionally included in the EUV PSM to secure a DoF. In next-generation products, the size shrinkage of a main feature may be required, and accordingly, the size shrinkage of the SRA F may also be required. However, when the width of the SRA F is greater than the width of the main feature by at least a certain ratio, the SRAF may be transferred to a wafer and form an unwanted pattern in the wafer. When the width of the SRAF is small, a pattern may not be reliably formed due to an insufficient exposure process margin caused by pattern line width roughness (LWR), a defect, such as pattern collapse, may occur in a process, such as a cleaning process, because an aspect ratio expressed as a width to height is high, and a mask lifetime may also be reduced. Here, the exposure process margin may be referred to as a patterning margin.

However, in the case of the EUV mask 100 of the present embodiment, the problems described above may be solved or mitigated because the first transfer pattern M p1 corresponding to a main feature has a multi-layer structure and the non-transfer pattern Sp corresponding to an SRAF has a single-layer structure. In detail, when the non-transfer pattern Sp has a single-layer structure, the non-transfer pattern Sp may not be transferred to a wafer even if the width of the non-transfer pattern Sp is relatively large. Accordingly, in the EUV mask 100 of the present embodiment, the non-transfer pattern Sp may be formed in a relatively large width, and accordingly, difficulty in forming a pattern due to an insufficient exposure process margin, pattern collapse in a process such as a cleaning process, or the reduction of a mask lifetime may be prevented or mitigated.

The peripheral pattern Bp may not be transferred to a wafer. For example, the peripheral pattern Bp may correspond to a structure defining the non-transfer region NPA rather than a pattern to be transferred to a wafer. As may be seen from FIG. 1A, like the first transfer pattern M p1, the peripheral pattern Bp may have a multi-layer structure including the first phase-shift layer 132, the buffer layer 134, and the second phase-shift layer 136. As may be seen from FIG. 1B, the peripheral pattern Bp may have a quadrangular ring shape surrounding the transfer region PA.

The backside conductive layer 140 may be disposed on the backside of the substrate 101. The backside conductive layer 140 may be formed to attach the EUV mask 100 to a mask stage. For example, the mask stage may include an electrostatic chuck, and the EUV mask 100 may be fixed to the electrostatic chuck by an electrostatic force through the backside conductive layer 140. For example, the backside conductive layer 140 may be formed by coating the backside of the substrate 101 with chromium nitride (CrN), which is a conductive material. However, the material of the backside conductive layer 140 is not limited to CrN in accordance with different embodiments.

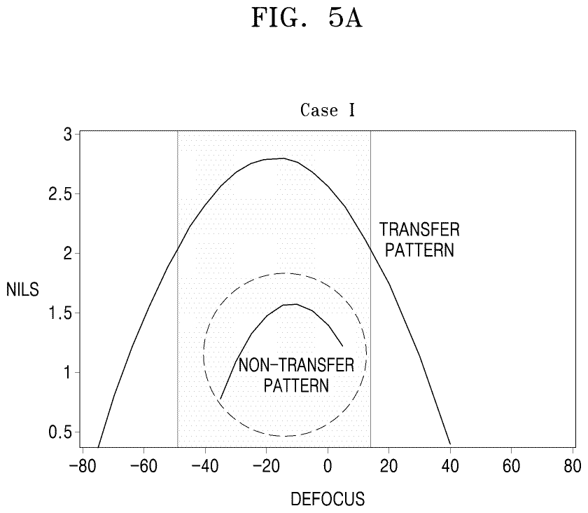

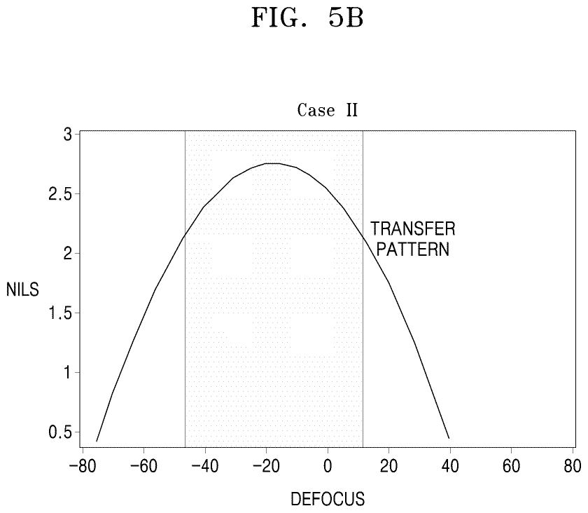

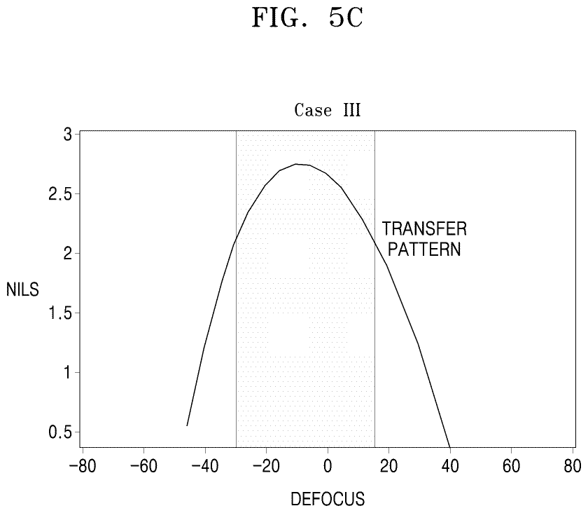

In the EUV mask 100 of the present embodiment, the first transfer pattern M p1 may have a multi-layer structure of the first phase-shift layer 132, the buffer layer 134, and the second phase-shift layer 136, and the non-transfer pattern Sp corresponding to an SRAF may have a single-layer structure of the first phase-shift layer 132. Accordingly, the EUV mask 100 of the present embodiment may have improved exposure characteristics, such as NILS and DoF, and may solve or mitigate problems that arise when an SRAF has a same structure as a transfer pattern. For example, in the case where an SRAF has a same structure as a transfer pattern, the SRAF may be transferred to a wafer when the width of the SRAF is large, and difficulty in forming a pattern due to an insufficient patterning margin, pattern collapse in a process such as a cleaning process, or the reduction of a mask lifetime that may occur when the width of the SRAF is small. However, in the EUV mask 100 of the present embodiment, the non-transfer pattern Sp may be formed in a relatively large width without being transferred to a wafer because the first transfer pattern M p1 has a multi-layer structure and the non-transfer pattern Sp has a single-layer structure. Accordingly, difficulty in forming a pattern, pattern collapse, or the reduction of a mask lifetime may be prevented or reduced. The exposure characteristics, such as NILS and DoF, of the EUV mask 100 of the present embodiment and the non-transfer effect of the non-transfer pattern Sp are described in detail with reference to FIGS. 5A to 5C below.

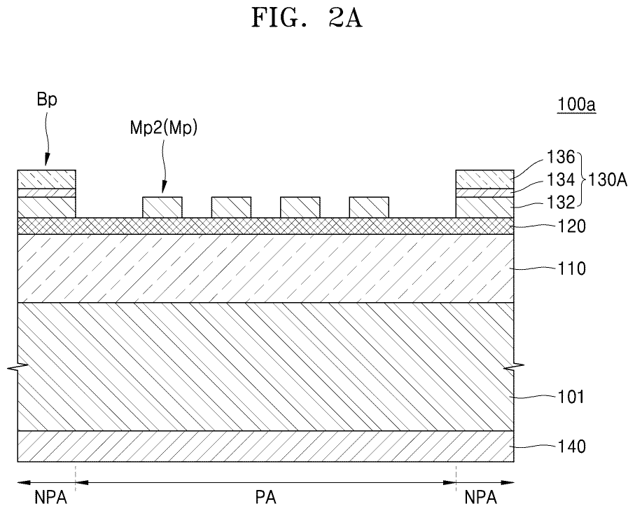

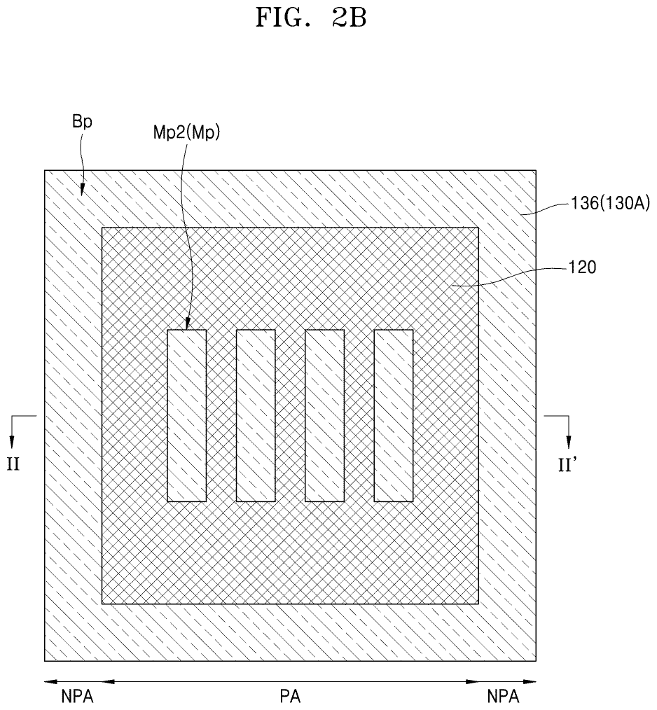

FIGS. 2A and 2B are respectively a cross-sectional view and a plan view of an EUV mask according to an embodiment. FIG. 2A is a cross-sectional view taken along line II-II′ in FIG. 2B. Redundant descriptions given above with reference to FIGS. 1A and 1B are brief or omitted.

Referring to FIGS. 2A and 2B, an EUV mask 100a of the present embodiment may be different from the EUV mask 100 of FIGS. 1A and 1B in light of a phase-shift structure 130A. In detail, the EUV mask 100a may include the substrate 101, the multi-reflective layer 110, the capping layer 120, the phase-shift structure 130A, and the backside conductive layer 140. The substrate 101, the multi-reflective layer 110, the capping layer 120, and the backside conductive layer 140 are the same as those described with reference to FIGS. 1A and 1B.

In the EUV mask 100a of the present embodiment, the phase-shift structure 130A may include only a transfer pattern M p and a peripheral pattern Bp and may not include a non-transfer pattern. The transfer pattern Mp may be arranged in the transfer region PA, and the peripheral pattern Bp may be arranged in the non-transfer region NPA. The peripheral pattern Bp may be substantially the same as the peripheral pattern Bp of the phase-shift structure 130 of the EUV mask 100 of FIGS. 1A and 1B.

The transfer pattern Mp may include a second transfer pattern M p2 having a single-layer structure. For example, the second transfer pattern M p2 may include only the first phase-shift layer 132 and may not include a buffer layer and a second phase-shift layer. The material or thickness of the first phase-shift layer 132 may be the same as that of the first phase-shift layer 132 of the phase-shift structure 130 of the EUV mask 100 of FIGS. 1A and 1B.

As shown in FIG. 2B, the second transfer pattern M p2 may have a line-and-space form. In the case of such a line-and-space pattern in a regular form, there is no pattern density imbalance, and therefore, it may be unnecessary to add a non-transfer pattern such as a SRA F.

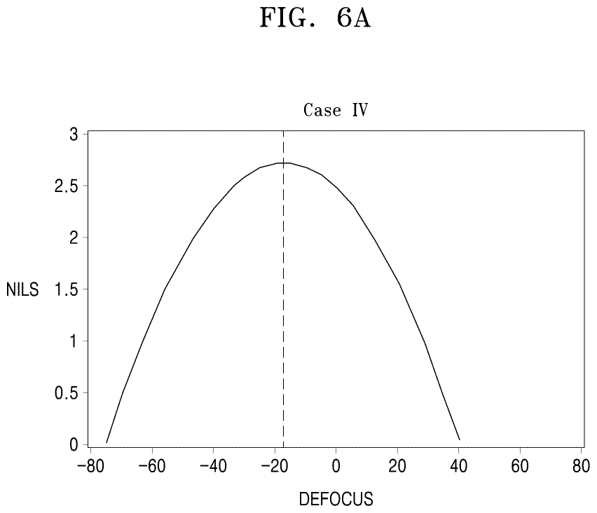

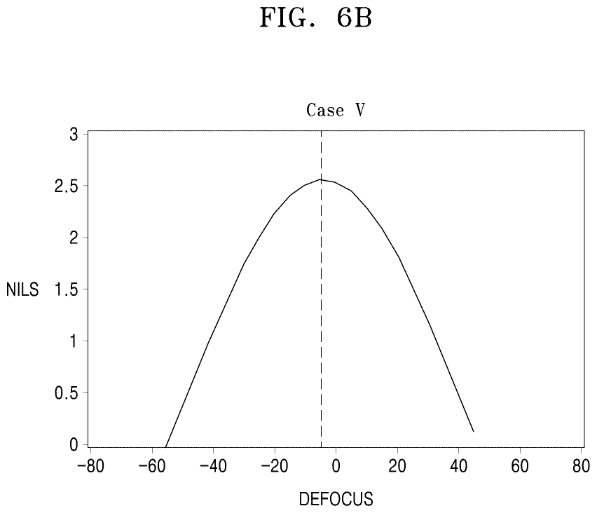

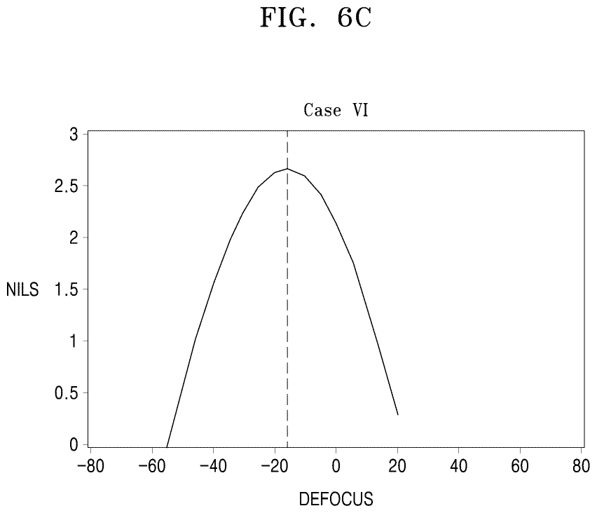

In the case of the EUV mask 100a of the present embodiment, an exposure characteristic related to best focus (BF) may be improved. The exposure characteristic related to the BF of the EUV mask 100 of the present embodiment is described in detail with reference to FIGS. 6A to 6C below.

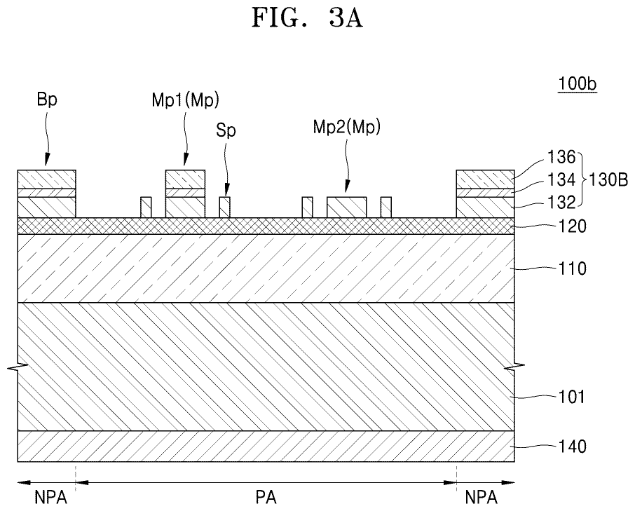

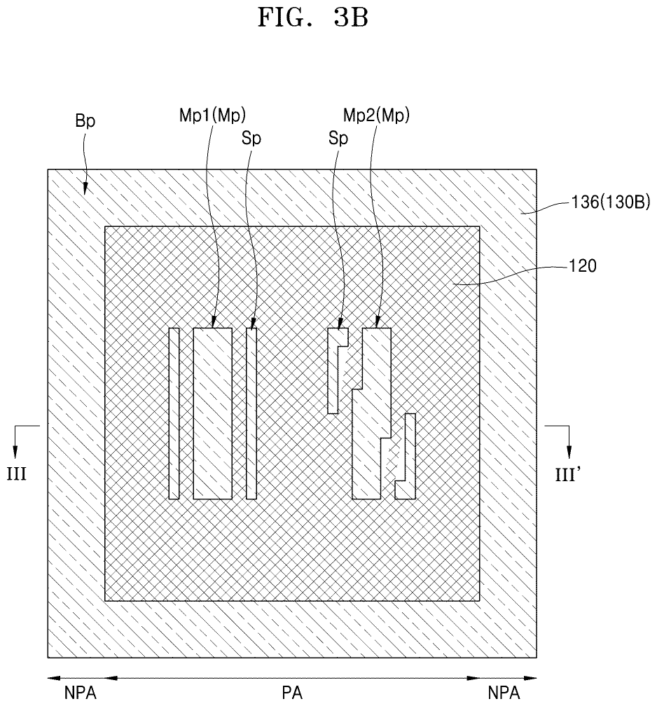

FIGS. 3A and 3B are respectively a cross-sectional view and a plan view of an EUV mask according to an embodiment. FIG. 3A is a cross-sectional view taken along line III-III′ in FIG. 3B. Redundant descriptions given above with reference to FIGS. 1A to 2B are brief or omitted.

Referring to FIGS. 3A and 3B, an EUV mask 100b of the present embodiment may be different from the EUV mask 100 of FIGS. 1A and 1B in light of a phase-shift structure 130B. In detail, the EUV mask 100b may include the substrate 101, the multi-reflective layer 110, the capping layer 120, the phase-shift structure 130B, and the backside conductive layer 140. The substrate 101, the multi-reflective layer 110, the capping layer 120, and the backside conductive layer 140 are the same as those described with reference to FIGS. 1A and 1B.

In the EUV mask 100b of the present embodiment, the phase-shift structure 130B may include a transfer pattern M p, a non-transfer pattern Sp, and a peripheral pattern Bp. The transfer pattern Mp and the non-transfer pattern Sp may be arranged in the transfer region PA, and the peripheral pattern Bp may be arranged in the non-transfer region NPA. The peripheral pattern Bp may be substantially the same as the peripheral pattern Bp of the phase-shift structure 130 of the EUV mask 100 of FIGS. 1A and 1B.

The transfer pattern Mp may include a first transfer pattern M p1 having a multi-layer structure and a second transfer pattern M p2 having a single-layer structure. For example, the first transfer pattern M p1 may have a triple-layer structure including the first phase-shift layer 132, the buffer layer 134, and the second phase-shift layer 136. The descriptions of the first transfer pattern M p1 are substantially the same as those of the first transfer pattern M p1 of the EUV mask 100 that have been given above with reference to FIGS. 1A and 1B.

The second transfer pattern M p2 may include only the first phase-shift layer 132. The descriptions of the material or thickness of the first phase-shift layer 132 are the same as those of the first phase-shift layer 132 of the phase-shift structure 130 of the EUV mask 100 that have been given above with reference to FIGS. 1A and 1B. As shown in FIG. 3B, in the EUV mask 100b of the present embodiment, the second transfer pattern M p2 may have an isolated line shape with a bent portion. For example, the first phase-shift layer 132 may have a line shape having a bent central portion. However, the shape of the second transfer pattern M p2 is not limited to a bent line shape in accordance with different embodiments. For example, the second transfer pattern M p2 may have other various shapes than the line shape.

The non-transfer pattern Sp may have a single-layer structure. For example, the non-transfer pattern Sp may include only the first phase-shift layer 132. The descriptions of the material or thickness of the first phase-shift layer 132 are the same as those of the first phase-shift layer 132 of the phase-shift structure 130 of the EUV mask 100 that have been given above with reference to FIGS. 1A and 1B. As may be seen from FIG. 3B, a non-transfer pattern Sp adjacent to the first transfer pattern M p1 may have a line shape. Contrarily, a non-transfer pattern Sp adjacent to the second transfer pattern M p2 may have a bent shape at each of opposite ends of the second transfer pattern M p2. However, the shape of the non-transfer pattern Sp is not limited thereto in accordance with different embodiments. For example, the non-transfer pattern Sp may have various shapes according to the shape of the transfer pattern M p adjacent thereto. The non-transfer pattern Sp may be omitted with respect to the transfer pattern M p having a particular shape.

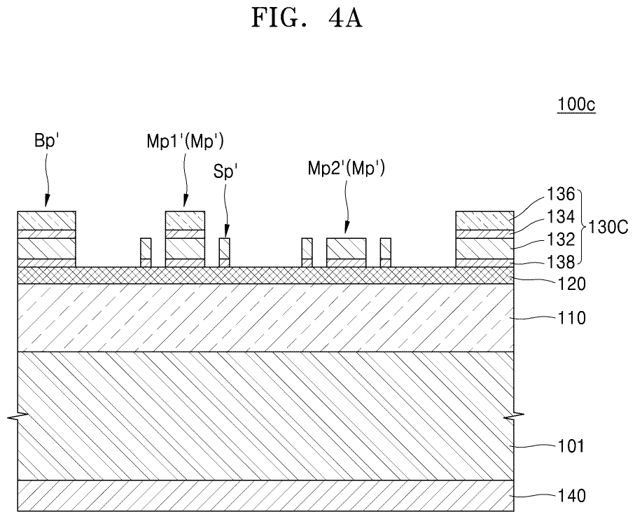

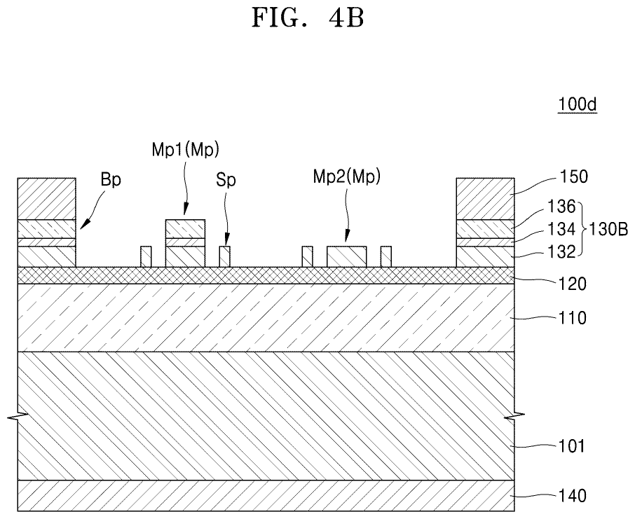

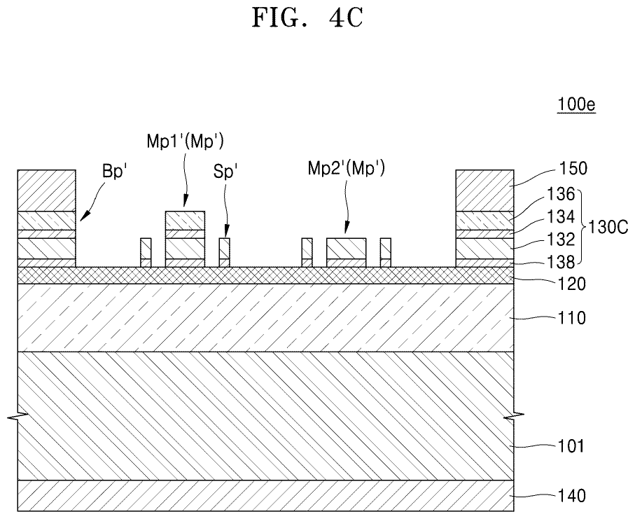

FIGS. 4A to 4C are cross-sectional views of an EUV mask according to an embodiment and may correspond to the cross-sectional view of FIG. 3A. FIG. 3B is also referred to in the description below. Redundant descriptions given above with reference to FIGS. 1A to 3B are brief or omitted.

Referring to FIG. 4A, an EUV mask 100c of the present embodiment may be different from the EUV mask 100b of FIG. 3A in light of a phase-shift structure 130C. In detail, the EUV mask 100c may include the substrate 101, the multi-reflective layer 110, the capping layer 120, the phase-shift structure 130C, and the backside conductive layer 140. The descriptions of the substrate 101, the multi-reflective layer 110, the capping layer 120, and the backside conductive layer 140 are the same as those given above with reference to FIGS. 3A and 3B.

In the EUV mask 100c of the present embodiment, the phase-shift structure 130C may further include an etch prevention layer 138 below the first phase-shift layer 132. Accordingly, each of a transfer pattern M p′, a non-transfer pattern Sp′, and a peripheral pattern Bp′ of the phase-shift structure 130C may further include the etch prevention layer 138 below the first phase-shift layer 132. In detail, each of a first transfer pattern M p1′ and a second transfer pattern M p2′ of the transfer pattern M p′ may further include the etch prevention layer 138 below the first phase-shift layer 132.

Because the etch prevention layer 138 is included in the phase-shift structure 130C, the shape of the etch stop layer 138 may have substantially the same shape as the layers above the etch prevention layer 138, as shown in FIG. 4A. The etch prevention layer 138 may act as an etch stop layer when the first phase-shift layer 132 is etched. Accordingly, the etch prevention layer 138 may have a high etch selectivity with respect to the first phase-shift layer 132. For example, the etch prevention layer 138 may have an etch selectivity of at least 1:5 with respect to the first phase-shift layer 132. In the EUV mask 100c of the present embodiment, the etch prevention layer 138 may have an etch selectivity of at least 1:10 with respect to the first phase-shift layer 132. However, the etch selectivity of the etch prevention layer 138 with respect to the first phase-shift layer 132 is not limited to those numerical ranges described above in accordance with different embodiments.

In the EUV mask 100c of the present embodiment, the etch prevention layer 138 may include substantially the same material as the buffer layer 134. For example, the etch prevention layer 138 may have a thickness of 10 nm or less. In the EUV mask 100c of the present embodiment, the etch prevention layer 138 may have a thickness of 5 nm or less. However, the thickness of the etch prevention layer 138 is not limited to the numerical ranges described above in accordance with different embodiments.

Referring to FIG. 4B, an EUV mask 100d of the present embodiment may be different from the EUV mask 100b of FIG. 3A in that the EUV mask 100d further includes an absorber layer 150. In detail, the EUV mask 100d of the present embodiment may include the substrate 101, the multi-reflective layer 110, the capping layer 120, the phase-shift structure 130B, the backside conductive layer 140, and the absorber layer 150. The descriptions of the substrate 101, the multi-reflective layer 110, the capping layer 120, the phase-shift structure 130B, and the backside conductive layer 140 are the same as those given above with reference to FIGS. 3A and 3B.

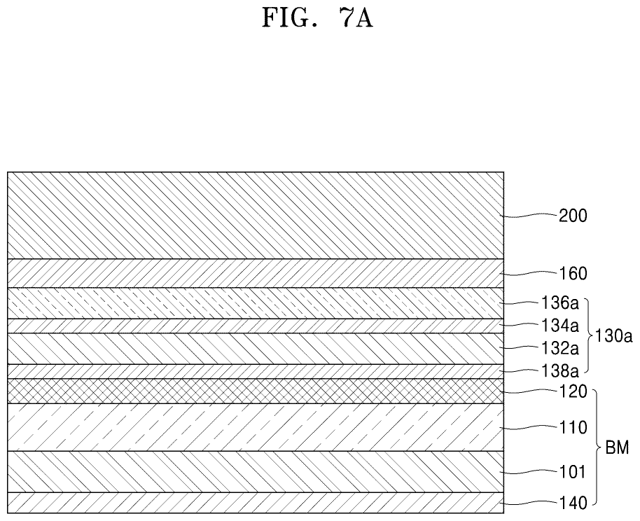

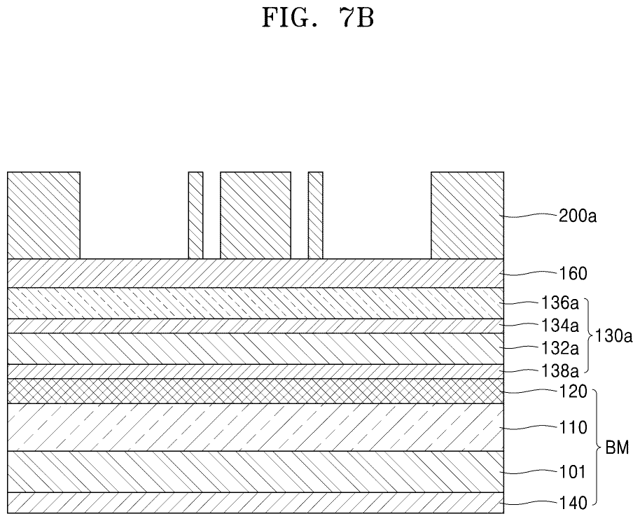

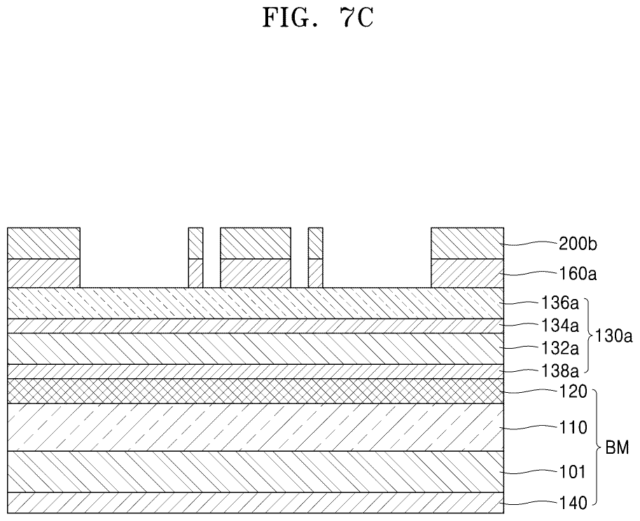

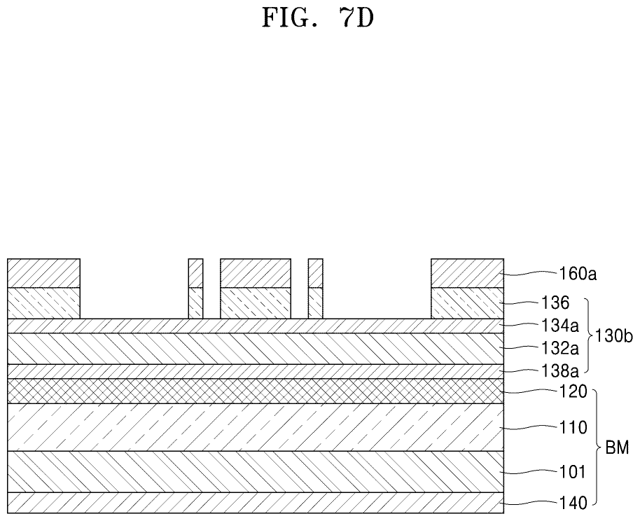

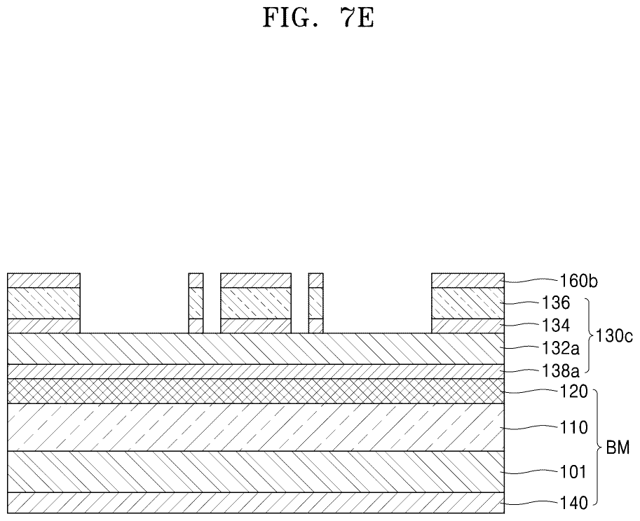

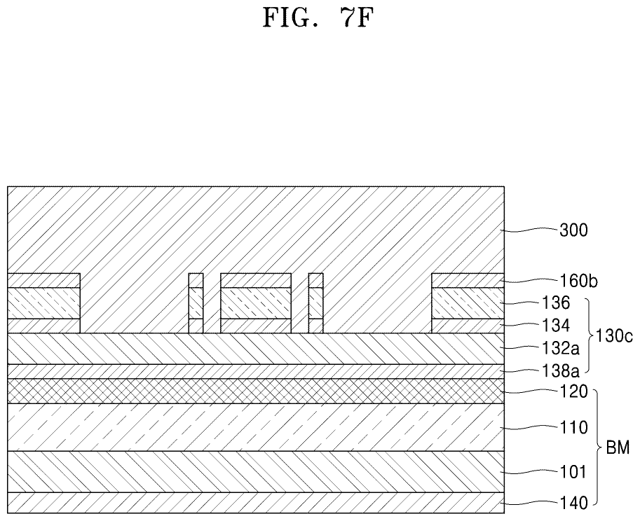

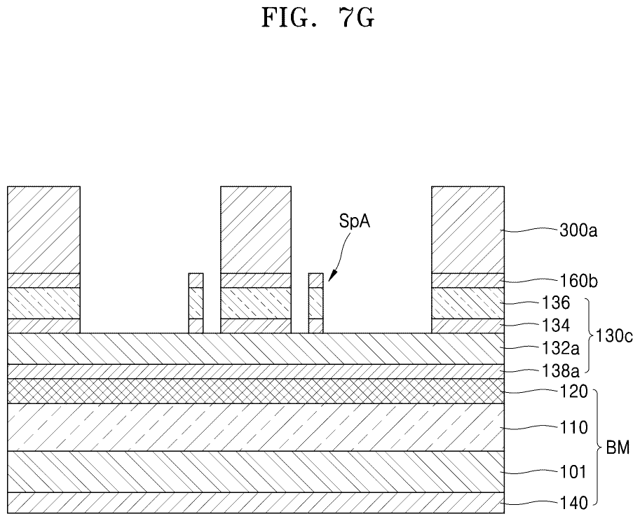

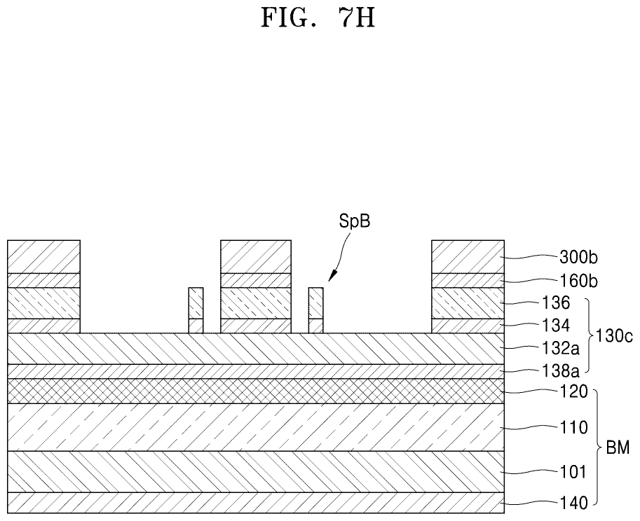

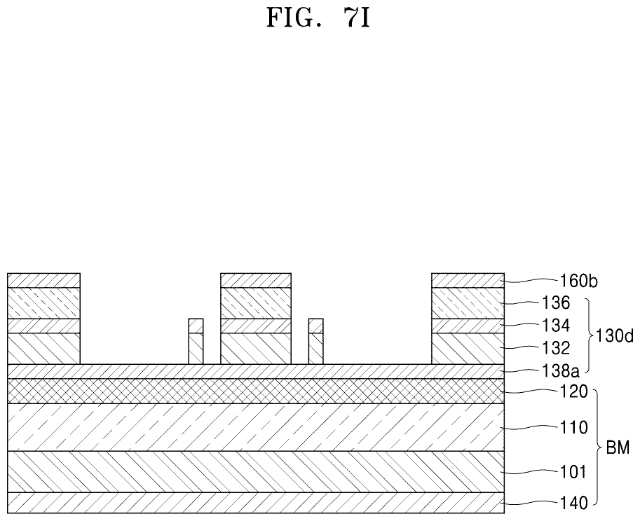

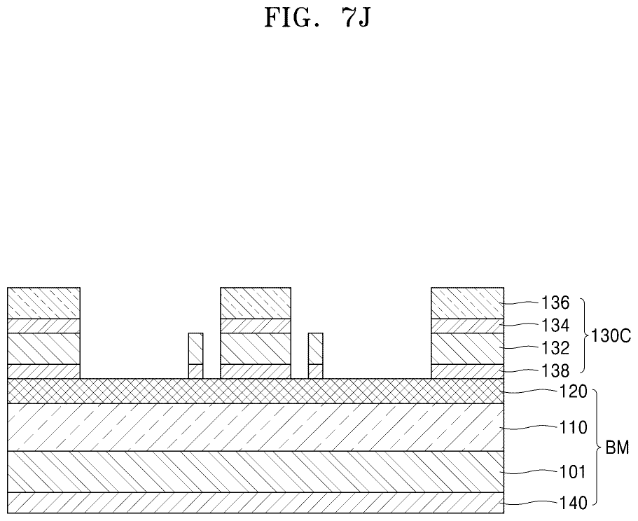

In the EUV mask 100d of the present embodiment, the absorber layer 150 may be disposed on the phase-shift structure 130B in the non-transfer region NPA. In detail, the absorber layer 150 may be disposed on the peripheral pattern Bp of the phase-shift structure 130B. Because the absorber layer 150 is disposed on the peripheral pattern Bp, the absorber layer 150 may have a quadrangular ring shape, like the peripheral pattern Bp. Although not shown, a hardmask layer (160a in FIG. 7C) may be between the absorber layer 150 and the peripheral pattern Bp.

The absorber layer 150 may include a material that is configured to absorb light, e.g., EUV light, which is incident to the absorber layer 150. Accordingly, the EUV light incident to the absorber layer 150 may not reach the capping layer 120 or the multi-reflective layer 110. The absorber layer 150 may include a tantalum (Ta)-group material. For example, the absorber layer 150 may include TaN, TaHf, TaHfN, TaBSi, TaBSIN, TaB, TaBN, TaSi, TaSIN, TaGe, TaGeN, TaZr, TaZrN, or a combination thereof. However, the material of the absorber layer 150 is not limited to those materials described above in accordance with different embodiments.

In the EUV mask 100d of the present embodiment, because the absorber layer 150 is arranged in the non-transfer region NPA, the peripheral pattern Bp may be fundamentally prevented from being transferred to a wafer. For example, even when EUV light is incident to the non-transfer region NPA in an EUV exposure process, the peripheral pattern Bp may not be transferred to a wafer because of the presence of the absorber layer 150.

Referring to FIG. 4C, an EUV mask 100e of the present embodiment may be different from the EUV mask 100b of FIG. 3A in that the EUV mask 100d includes the phase-shift structure 130C and further includes the absorber layer 150. In detail, the EUV mask 100e of the present embodiment may include the substrate 101, the multi-reflective layer 110, the capping layer 120, the phase-shift structure 130C, the backside conductive layer 140, and the absorber layer 150. The descriptions of the substrate 101, the multi-reflective layer 110, the capping layer 120, and the backside conductive layer 140 are the same as those given above with reference to FIGS. 3A and 3B.

In the EUV mask 100e of the present embodiment, the phase-shift structure 130C may further include the etch prevention layer 138 below the first phase-shift layer 132. The description of the phase-shift structure 130C is the same as the description of the phase-shift structure 130C of the EUV mask 100c that is given above with reference to FIG. 4A.

In the EUV mask 100e of the present embodiment, the absorber layer 150 may be disposed on the phase-shift structure 130C in the non-transfer region NPA. In detail, the absorber layer 150 may be disposed on the peripheral pattern Bp′ of the phase-shift structure 130C. The description of the absorber layer 150 is the same as the description of the absorber layer 150 of the EUV mask 100d that is given above with reference to FIG. 4B.

Although structures in which the first transfer pattern M p1 or M p1′ includes three or four layers and each of the non-transfer pattern Sp or Sp′ and the second transfer pattern M p2 or M p2′ includes a single layer or two layers have been described, embodiments are not limited to those structures. For example, a first transfer pattern may include five or more layers having a buffer layer between the layers. A non-transfer pattern and a second transfer pattern may have other layered structures than a single-layer or dual-layer structure. However, as described above, even when a transfer pattern and a non-transfer pattern have different layered structures, the total thickness of a phase-shift layer may be 60 nm or less.

FIGS. 5A to 5C are simulation graphs illustrating exposure characteristics in three different EUV mask structures. The simulation graphs of FIGS. 5A to 5C each show NILS versus defocus. In the graphs, the x-axis indicates defocus in units of nm, and the y-axis indicates NILS without units.

Referring to FIGS. 5A to 5C, in three cases of EUV mask structures, a transfer pattern may have an isolated line shape and a non-transfer pattern may be a line-shaped scattering bar adjacent to the transfer pattern. In all three cases, like the first transfer pattern M p1′ in FIG. 4A, the transfer pattern may have a quadruple-layer structure including an etch prevention layer, a first phase-shift layer, a buffer layer, and a second phase-shift layer. In Case I, the non-transfer pattern may have a quadruple-layer structure including an etch prevention layer, a first phase-shift layer, a buffer layer, and a second phase-shift layer. In Case II, the non-transfer pattern may have a dual-layer structure including the etch prevention layer and the first phase-shift layer. In Case III, there is no non-transfer pattern. The first phase-shift layer and the second phase-shift layer may include Ru, and the etch prevention layer and the buffer layer may include Ta₂O₅. The total thickness of a phase-shift structure may be 60 nm or less.

The optical characteristics of evaluation items are NILS, DoF, and whether a non-transfer pattern is transferred. Here, the NILS indicates patterning performance. As the value of the NILS increases, the change of a critical dimension (CD) decreases with respect to a process change. The higher the value of the NILS, the better the optical characteristics may be evaluated. The shaded portion in each graph may correspond to a focus window and may be used to calculate the DoF.

Table 1 shows the optical characteristics in three cases, i.e., Case I, Case II, and Case III.

TABLE 1

| | Transfer | | Non-transfer | | | | |
|---|---|---|---|---|---|---|---|
| | pattern | | pattern | | Maxi- | | |
| | Number | | Number | | mum | | Non- |
| Items | of | Aspect | of | Aspect | NILS | DoF | transfer |
| Case I | 4 | 1:5 | 4 | 1:8 | 2.80 | 64.2 | ∘ |
| Case II | 4 | 1:5 | 2 | 1:5 | 2.73 | 58.7 | x |
| Case III | 4 | 1:5 | 0 | N/A | 2.72 | 45.6 | x |

As may be seen from Table 1, in Case I in which a non-transfer pattern has the same structure as a transfer pattern, a defect in which the non-transfer pattern is transferred to a wafer may occur. For example, in the graph of FIG. 5A, it may be seen that a curve corresponding to the non-transfer pattern appears in a dashed-line circle together with a curve corresponding to the transfer pattern.

In Case II in which a non-transfer pattern includes a lower number of layers than a transfer pattern, for example, two layers, the non-transfer pattern is not transferred and the NILS and the DoF remain similar to Case I. In Case III in which no non-transfer pattern is formed at all, it may be seen that the DoF is significantly different compared to Case I. In detail, in Case III, it may be seen that the DoF is improved by at least 25% compared to Case III.

Case I may correspond to a general EUV mask in which a non-transfer pattern has the same layered structure as a transfer pattern. Case II may correspond to the EUV masks 100 and 100b to 100e of FIGS. 1A, 3A, and 4A to 4C in which the non-transfer pattern Sp has a different layered structure than the transfer pattern Mp. Case III may correspond to an EUV mask according to the related art in which an SRA F is not used.

FIGS. 6A to 6C are graphs illustrating exposure characteristics in three different EUV mask structures. FIGS. 6A to 6C are simulation graphs showing exposure characteristics in different EUV mask structures. The simulation graphs of FIGS. 6A to 6C each show NILS versus defocus. In the graphs, the x-axis indicates defocus in units of nm, and the y-axis indicates NILS without units.

Referring to FIGS. 6A to 6C, in three cases of EUV mask structures, Case IV may be the same as Case II described above with reference to FIGS. 5A to 5C. Accordingly, a transfer pattern may have an isolated line shape and a non-transfer pattern may be a line-shaped scattering bar adjacent to the transfer pattern. The transfer pattern may have a quadruple-layer structure, and the non-transfer pattern may have a dual-layer structure. In Case V and Case VI, the transfer pattern may have a line-and-space form and there is no non-transfer pattern. In Case V, the transfer pattern may have a quadruple-layer structure including an etch prevention layer, a first phase-shift layer, a buffer layer, and a second phase-shift layer. In Case VI, the transfer pattern may have a dual-layer structure including the etch prevention layer and the first phase-shift layer. The materials of layers and the total thickness of a phase-shift structure are the same as those described above with reference to FIGS. 5A to 5C.

The optical characteristic of an evaluation item is BF. The shift of BF may be evaluated on the basis of BF in Case IV. The less the shift of BF, the better the optical characteristic may be evaluated. In each of the graphs of FIGS. 6A to 6C, the dashed line may correspond to a BF position.

Table 2 shows the optical characteristic in three cases, i.e., Case IV, Case V, and Case VI.

TABLE 2

| | Number of layers in | Number of layers in non- | |
|---|---|---|---|
| Items | transfer pattern | transfer pattern | Best Focus |
| Case IV | 4 | 2 | −17.5 nm |
| Case V | 4 | 0 | −4.9 nm |
| Case VI | 2 | 0 | −15.9 nm |

As may be seen from Table 2, in Case IV and Case V in which the transfer pattern has a quadruple-layer structure, there is a significant difference in BF between Case IV and Case V. In detail, it may be seen that the BF in Case V shifts at least 12 nm compared to the BF in Case IV. In Case VI in which the transfer pattern has a dual-layer structure, that is, the transfer pattern includes one phase-shift layer, it may be seen that the difference in BF is not significant compared to Case IV. In detail, compared to Case IV, it may be seen that the BF shifts 2 nm or less in Case VI. Accordingly, when a transfer pattern has a line-and-space structure, as shown in the EUV mask 100a of FIG. 2A, the shift of BF may be greatly improved by forming a transfer pattern having a structure including one phase-shift layer.

FIGS. 7A to 7J are cross-sectional views schematically illustrating a method of manufacturing an EUV mask, according to an embodiment. FIG. 4A is also referred to in the description below. Redundant descriptions given above with reference to FIGS. 1A to 6C are brief or omitted.

Referring to FIG. 7A, a blank EUV mask BM may be prepared. The blank EUV mask BM may include the substrate 101, the multi-reflective layer 110, the capping layer 120, and the backside conductive layer 140. Thereafter, a phase-shift structure layer 130a, a hardmask layer 160, and a first resist 200 may be sequentially stacked on the blank EUV mask BM. The phase-shift structure layer 130a may include an etch prevention layer 138a, a first phase-shift layer 132a, a buffer layer 134a, and a second phase-shift layer 136a, which are sequentially stacked from the bottom of the phase-shift structure layer 130a.

The descriptions of the first phase-shift layer 132a and the second phase-shift layer 136a are the same as those of the first phase-shift layer 132 and the second phase-shift layer 136 of the phase-shift structure 130 of the EUV mask 100 of FIG. 1A. Accordingly, the first phase-shift layer 132a and the second phase-shift layer 136a may include substantially the same material.

The buffer layer 134a is substantially the same as the buffer layer 134 of the phase-shift structure 130 of the EUV mask 100 of FIG. 1A. The etch prevention layer 138a is substantially the same as the etch prevention layer 138 of the phase-shift structure 130C of the EUV mask 100c of FIG. 4A.

Similar to the buffer layer 134a or the etch prevention layer 138a, the hardmask layer 160 may have a high etch selectivity with respect to the second phase-shift layer 136a. Accordingly, in the method of manufacturing an EUV mask, the etch prevention layer 138a, the buffer layer 134a, and the hardmask layer 160 may include the same material. However, the materials of the etch prevention layer 138a, the buffer layer 134a, and the hardmask layer 160 are not limited thereto. The etch prevention layer 138a and the buffer layer 134a may have similar thicknesses to each other, and the hardmask layer 160 may be thicker than the etch prevention layer 138a or the buffer layer 134a. For example, the thickness of the hardmask layer 160 may be at least twice the thickness of the buffer layer 134a.

Referring to FIG. 7B, a first resist pattern 200a may be formed by patterning the first resist 200. For example, the first resist 200 may include an E-beam resist. The first resist pattern 200a may be formed by patterning the first resist 200 through an E-beam exposure process.

Referring to FIG. 7C, after the first resist pattern 200a is formed, a hardmask layer 160a may be formed by etching the hardmask layer 160 by using the first resist pattern 200a as an etch mask.

Referring to FIG. 7D, the second phase-shift layer 136 may be formed by etching the second phase-shift layer 136a by using the first resist pattern 200b and/or the hardmask layer 160a as an etch mask. A phase-shift structure layer 130b may be formed by forming the second phase-shift layer 136.

Referring to FIG. 7E, the buffer layer 134 may be formed by etching the buffer layer 134a by using the hardmask layer 160a as an etch mask. As described above, the hardmask layer 160a and the buffer layer 134a may include substantially the same material and thus have substantially the same etch rate. When the thickness of the hardmask layer 160a is about twice the thickness of the buffer layer 134a before the buffer layer 134a is etched, the thickness of a hardmask layer 160b may be half the thickness of the hardmask layer 160a after the buffer layer 134a is etched. When the thickness of the hardmask layer 160a is greater than twice the thickness of the buffer layer 134a before the buffer layer 134a is etched, the thickness of a hardmask layer 160b may be greater than half the thickness of the hardmask layer 160a after the buffer layer 134a is etched. A phase-shift structure layer 130c may be formed by forming the buffer layer 134.

Referring to FIG. 7F, after the buffer layer 134 is formed, a second resist 300 may be formed to cover the entire upper structure of the blank EUV mask BM. For example, the second resist 300 may include an E-beam resist.

Referring to FIG. 7G, a second resist pattern 300a may be formed by patterning the second resist 300. For example, the second resist pattern 300a may be formed by patterning the second resist 300 through an E-beam exposure process. By forming the second resist pattern 300a, an initial non-transfer pattern SpA of the phase-shift structure layer 130c may be exposed. The initial non-transfer pattern SpA may include the hardmask layer 160b at its top.

Referring to FIG. 7H, after the second resist pattern 300a is formed, an initial non-transfer pattern SpB may be formed by removing the hardmask layer 160b of the initial non-transfer pattern SpA through etching using the second resist pattern 300a as an etch mask.

Referring to FIG. 7I, the first phase-shift layer 132 may be formed by etching the first phase-shift layer 132a by using the second resist pattern 300b and/or the hardmask layer 160b as an etch mask. A phase-shift structure layer 130d may be formed by forming the first phase-shift layer 132.

Thereafter, referring to FIG. 7J, the etch prevention layer 138 may be formed by etching the etch prevention layer 138a by using the hardmask layer 160b as an etch mask. As described above, the hardmask layer 160b and the etch prevention layer 138a may include substantially the same material and thus have substantially the same etch rate. As a result, when the etch prevention layer 138a is etched, the hardmask layer 160b may also be removed. In detail, when half the hardmask layer 160b remains in the process of forming the buffer layer 134 in FIG. 7E, the thickness of the hardmask layer 160b may be substantially the same as the thickness of the etch prevention layer 138, and accordingly, the hardmask layer 160b may also be removed when the etch prevention layer 138a is etched. When more than half the hardmask layer 160b remains in the process of forming the buffer layer 134 in FIG. 7E, the thickness of the hardmask layer 160b may be greater than the thickness of the etch prevention layer 138. Accordingly, when the etch prevention layer 138a is etched, a portion of the hardmask layer 160b may remain with a certain thickness.

By forming the etch prevention layer 138, the phase-shift structure 130C may be completely formed, and accordingly, the EUV mask 100c of FIG. 4A may be manufactured.

Although the method of manufacturing the EUV mask 100c of FIG. 4A has been described, embodiments of an EUV mask manufacturing method are not limited thereto. For example, the EUV masks 100, 100a, and 100b of FIGS. 1A, 2A, and 3A may be manufactured by appropriately adjusting the thicknesses and positions of an etch prevention layer, a buffer layer, and a hardmask layer and patterning the etch prevention layer, the buffer layer, and the hardmask layer. The EUV masks 100d and 100E of FIGS. 4B and 4C may be manufactured by additionally arranging an absorber layer on the second phase-shift layer 136a. Furthermore, an EUV mask having a phase-shift structure including five or more layers may be manufactured by introducing at least three phase-shift layers and an additional buffer layer.

While the inventive concept has been particularly shown and described with reference to embodiments thereof, it will be understood that various changes in form and details may be made therein without departing from the spirit and scope of the following claims.

What is claimed is:

1. An extreme ultraviolet (EUV) mask comprising:
a substrate having a reflective mask thereon;
a multi-reflective layer on a top surface of the substrate and including a plurality of layers comprising two kinds of material layers alternately stacked; and
a phase-shift structure on the multi-reflective layer and including a transfer pattern and a non-transfer pattern,
wherein the transfer pattern includes a first transfer pattern having a multi-layer structure,
wherein the non-transfer pattern has a layered structure; and
wherein an upper surface of the non-transfer pattern is closer to the substrate than an upper surface of the first transfer pattern.

2. The EUV mask of claim 1, wherein
the transfer pattern is configured to be transferred to a wafer in an EUV exposure process,
the non-transfer pattern is not configured to be transferred to the wafer in the EUV exposure process,
the first transfer pattern includes a first phase-shift layer, a buffer layer, and a second phase-shift layer that are sequentially stacked, and
the non-transfer pattern includes the first phase-shift layer.

3. The EUV mask of claim 2, wherein
the first phase-shift layer and the second phase-shift layer include substantially identical materials to each other, and
the buffer layer has an etch selectivity of at least 1:5 with respect to the first phase-shift layer.

4. The EUV mask of claim 2, wherein
the first phase-shift layer includes a first material for adjusting a refractive index and an extinction coefficient and a second material for improving a process characteristic, and
the first phase-shift layer additionally includes a third material of a light element.

5. The EUV mask of claim 4, wherein
the first material includes at least one element selected from the group consisting of Pd, Rh, Ru, Tc, Mo, Nb, Zr, and Y,
the second material includes at least one metal, and
the third material includes at least one element selected from the group consisting of H, He, B, C, O, and N.

6. The EUV mask of claim 1, wherein the transfer pattern further includes a second transfer pattern having a substantially identical layered structure to that of the non-transfer pattern.

7. The EUV mask of claim 6, wherein
the first transfer pattern has an isolated line shape,
the second transfer pattern has a line-and-space form, and
the non-transfer pattern is adjacent to the first transfer pattern.

8. The EUV mask of claim 1, further comprising:
a backside conductive layer on a bottom surface of the substrate; and
a capping layer on the multi-reflective layer,
wherein the phase-shift structure is on the capping layer.

9. The EUV mask of claim 1, wherein the phase-shift structure further includes an etch prevention layer in a lower portion thereof.

10. The EUV mask of claim 1, wherein
the EUV mask is divided into a transfer region in a central portion of the EUV mask and a non-transfer region surrounding the transfer region in a plan view,
the transfer pattern and the non-transfer pattern are arranged in the transfer region, and
the non-transfer region includes the multi-layer structure or an arrangement of the multi-layer structure and an absorber layer.

11. An extreme ultraviolet (EUV) mask comprising:
a substrate having a reflective mask thereon;
a backside conductive layer on a bottom surface of the substrate;
a multi-reflective layer on a top surface of the substrate and including a plurality of layers comprising two kinds of material layers alternately stacked;
a capping layer on the multi-reflective layer; and
a phase-shift structure on the capping layer,
wherein the phase-shift structure includes a first transfer pattern, a second transfer pattern, and a non-transfer pattern, the first transfer pattern having a multi-layer structure, and the second transfer pattern and the non-transfer pattern each having a layered structure, and
wherein upper surfaces of the second transfer pattern and the non-transfer pattern, respectively, are closer to the substrate than an upper surface of the first transfer pattern.

12. The EUV mask of claim 11, wherein
the first transfer pattern includes a first phase-shift layer, a buffer layer, and a second phase-shift layer that are sequentially stacked, and
the non-transfer pattern includes the first phase-shift layer.

13. The EUV mask of claim 12, wherein
the first phase-shift layer and the second phase-shift layer include substantially identical materials to each other, and
the buffer layer has an etch selectivity of at least 1:5 with respect to the first phase-shift layer.

14. The EUV mask of claim 12, wherein
the first phase-shift layer includes a first material for adjusting a refractive index and an extinction coefficient, and a second material for improving a process characteristic, and
the first phase-shift layer additionally includes a third material of a light element.

15. The EUV mask of claim 11, wherein
the first transfer pattern includes an isolated line shape,
the second transfer pattern includes a line-and-space form, and
the non-transfer pattern is adjacent to the first transfer pattern.

16. The EUV mask of claim 11, wherein the phase-shift structure further includes an etch prevention layer in a lower portion thereof.

17. An extreme ultraviolet (EUV) mask comprising:
a substrate having a reflective mask thereon;
a multi-reflective layer on a top surface of the substrate and including a plurality of layers comprising two kinds of material layers alternately stacked;
a capping layer on the multi-reflective layer; and
a phase-shift structure on the multi-reflective layer and including a transfer pattern and a non-transfer pattern,
wherein the transfer pattern includes a first transfer pattern having a multi-layer structure and a second transfer pattern having a layered structure,
wherein an upper surface of the second transfer pattern is closer to the substrate than an upper surface of the first transfer pattern.

18. The EUV mask of claim 17, wherein
the first transfer pattern includes a first phase-shift layer, a buffer layer, and a second phase-shift layer that are sequentially stacked, and
the non-transfer pattern has a substantially identical layered structure to that of the second transfer pattern and includes the first phase-shift layer,
the first phase-shift layer and the second phase-shift layer include substantially identical materials to each other, and
the buffer layer has an etch selectivity of at least 1:5 with respect to the first phase-shift layer.

19. The EUV mask of claim 18, wherein
the first phase-shift layer includes a first material, a second material, and a third material,
the first material includes at least one element selected from the group consisting of Pd, Rh, Ru, Tc, Mo, Nb, Zr, and Y,
the second material includes at least one metal, and
the third material includes at least one element selected from the group consisting of H, He, B, C, O, and N.

20. The EUV mask of claim 17, wherein
the first transfer pattern includes an isolated line shape or an at least partially curved line shape,
the second transfer pattern includes a line-and-space form or a line shape with a bent portion, and
the non-transfer pattern is adjacent to the first transfer pattern or the second transfer pattern having the line shape with the bent portion.
